(19) United States
(12) Patent Application Publication
(10) Pub. No.: US 2025/0366346 A1
(43) Pub. Date: Nov. 27, 2025

(54) DISPLAY DEVICE, WEARABLE ELECTRONIC DEVICE, AND METHOD OF MANUFACTURING DISPLAY DEVICE

(71) Applicant: Samsung Display Co., LTD., Yongin-si (KR)

(72) Inventor: Chun Gi YOU, Yongin-si (KR)

(73) Assignee: Samsung Display Co., LTD., Yongin-si (KR)

(21) Appl. No.: 19/071,124

(22) Filed: Mar. 5, 2025

(30) Foreign Application Priority Data
May 24, 2024 (KR) 10-2024-0067777

(51) Int. Cl. H10K 59/80; H10K 59/12; H10K 59/122

(52) U.S. Cl. CPC H10K 59/80518; H10K 59/1201; H10K 59/122

(57) ABSTRACT

Provided is a display device including a first sub-pixel, a second sub-pixel, and a third sub-pixel. Each of the first sub-pixel, the second sub-pixel, and the third sub-pixel includes: a reflective electrode disposed on a base layer; a first electrode disposed on the reflective electrode; a pixel defining layer disposed on the reflective electrode; a light emitting member disposed on the first electrode and the pixel defining layer; and a second electrode disposed on the light emitting member. The first electrode of the first sub-pixel is disposed on the pixel defining layer, and the first electrode of the second sub-pixel is disposed between the reflective electrode and the pixel defining layer.

### CROSS-REFERENCE TO RELATED APPLICATION(S)

The application claims priority to and benefits of Korean patent application No. 10-2024-0067777 under 35 U.S.C. § 119, filed on May 24, 2024, in the Korean Intellectual Property Office, the entire contents of which are incorporated herein by reference.

### BACKGROUND

### 1. Technical Field

The disclosure generally relates to a display device. More particularly, the disclosure relates to a display device, a wearable electronic device, and a method of manufacturing a display device.

### 2. Description of the Related Art

Research and development of display devices have been ongoing recently due to the growing interest in information displays. As a result, there is a greater demand for the display device to have better display quality.

### SUMMARY

Embodiments provide a high-luminance display device and a method of manufacturing a high-luminance display device.

In accordance with an aspect of the disclosure, there is provided a display device including a first sub-pixel, a second sub-pixel, and a third sub-pixel, wherein each of the first sub-pixel, the second sub-pixel, and the third sub-pixel includes: a reflective electrode disposed on a base layer; a first electrode disposed on the reflective electrode; a pixel defining layer disposed on the reflective electrode; a light emitting member disposed on the first electrode and the pixel defining layer; and a second electrode disposed on the light emitting member, wherein the first electrode of the first sub-pixel is disposed on the pixel defining layer, and wherein the first electrode of the second sub-pixel is disposed between the reflective electrode and the pixel defining layer.

The first electrode of the third sub-pixel may be disposed between the reflective electrode and the pixel defining layer.

The first electrode of the first sub-pixel may be electrically connected to the reflective electrode of the first sub-pixel through a contact hole at least partially penetrating the pixel defining layer. The first electrode of the second sub-pixel may be disposed on the reflective electrode of the second sub-pixel and is in direct contact with the reflective electrode of the second sub-pixel.

The pixel defining layer may include at least one of silicon oxide and silicon nitride.

A distance between the reflective electrode and the first electrode in the first sub-pixel may be about ¼ of a wavelength band of light which the first sub-pixel emits to an outside.

The first sub-pixel may emit light in a red wavelength band, and a thickness of the pixel defining layer on the reflective electrode may be in a range of about 1500 Å to about 1900 Å.

The distance between the reflective electrode and the first electrode in the first sub-pixel may be about 1700 Å.

The pixel defining layer may include an opening exposing the first electrode of the second sub-pixel, and include no opening overlapping the first sub-pixel.

In a plan view, an emission area of the first sub-pixel may overlap the first electrode of the first sub-pixel, and an emission area of the second sub-pixel may overlap the opening smaller than the first electrode of the second sub-pixel.

The pixel defining layer may include a first layer, a second layer disposed on the first layer, and a third layer disposed on the second layer.

The first electrode may include a titanium, titanium nitride, or tantalum nitride.

The first electrode may include indium tin oxide, indium zinc oxide, zinc oxide, indium gallium zinc oxide, or indium tin zinc oxide.

The light emitting member may include a first light emitting layer emitting light of a first color and a second light emitting layer which is disposed on the first light emitting layer and emits light of a second color different from the first color.

In accordance with another aspect of the disclosure, there is provided a wearable electronic device including: a display panel outputting light; and at least one lens disposed on the display panel, wherein the display panel includes a first sub-pixel, a second sub-pixel, and a third sub-pixel, wherein each of the first sub-pixel, the second sub-pixel, and the third sub-pixel includes: a reflective electrode disposed on a base layer; a first electrode disposed on the reflective electrode; a pixel defining layer disposed on the reflective electrode; a light emitting member disposed on the first electrode and the pixel defining layer; and a second electrode disposed on the light emitting member, wherein the first electrode of the first sub-pixel is disposed on the pixel defining layer, and wherein the first electrode of the second sub-pixel is disposed between the reflective electrode and the pixel defining layer.

In accordance with still another aspect of the disclosure, there is provided a method of manufacturing a display device, the method including: forming, on a base layer, a reflective electrode of each of a first sub-pixel, a second sub-pixel, and a third sub-pixel; forming a first electrode of the second sub-pixel on the reflective electrode; forming a pixel defining layer covering the first electrode of the second sub-pixel; forming a first electrode of the first sub-pixel on the pixel defining layer; forming, in the pixel defining layer, an opening exposing the first electrode of the second sub-pixel; and forming a light emitting member on the first electrode of the first sub-pixel and the first electrode of the second sub-pixel, which is exposed by the opening.

Between the base layer and the light emitting member, the third sub-pixel and the second sub-pixel may have a same stacked structure.

The first electrode of the first sub-pixel may be electrically connected to the reflective electrode of the first sub-pixel through a contact hole penetrating the pixel defining layer. The first electrode of the second sub-pixel may be disposed on the reflective electrode of the second sub-pixel and is in direct contact with the reflective electrode of the second sub-pixel.

The forming of the first electrode of the second sub-pixel may include: forming an electrode layer for the first electrode on the reflective electrode; etching the reflective electrode and the electrode layer between the first to third sub-pixels; and etching the electrode layer on the first sub-pixel.

The pixel defining layer may include at least one of silicon oxide and silicon nitride.

The first electrode of each of the first to third sub-pixels may include a titanium, titanium nitride, or tantalum nitride.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a schematic block diagram illustrating an embodiment of a display device of the disclosure.

FIG. 2 is a schematic block diagram illustrating an embodiment of any one of sub-pixels shown in FIG. 1.

FIG. 3 is a schematic circuit diagram illustrating an embodiment of the sub-pixel shown in FIG. 2.

FIG. 4 is a schematic plan view illustrating an embodiment of a display panel shown in FIG. 1.

FIG. 5 is an exploded schematic perspective view illustrating a portion of the display panel shown in FIG. 4.

FIG. 6 is a schematic plan view illustrating an embodiment of any one of pixels shown in FIG. 5.

FIG. 7 is a schematic cross-sectional view taken along line I-I′ shown in FIG. 6.

FIGS. 8A, 8B, and 8C are enlarged schematic cross-sectional views illustrating a portion of a light emitting element layer shown in FIG. 7.

FIG. 9 is a schematic cross-sectional view illustrating a comparative example of the portion of a light emitting element layer shown in FIG. 7.

FIG. 10 is a schematic cross-sectional view illustrating an embodiment of a light emitting structure included in any one of first to third light emitting elements shown in FIG. 7.

FIG. 11 is a schematic cross-sectional view illustrating another embodiment of the light emitting structure included in the one of the first to third light emitting elements shown in FIG. 7.

FIG. 12 is a schematic plan view illustrating another embodiment of the one of the pixels shown in FIG. 5.

FIG. 13 is a schematic plan view illustrating still another embodiment of the one of the pixels shown in FIG. 5.

FIG. 14 is a schematic block diagram illustrating an embodiment of a display system.

FIG. 15 is a schematic perspective view illustrating an application example of the display system shown in FIG. 14.

FIG. 16 is a schematic view illustrating a head-mounted display device shown in FIG. 14, which is worn by a user.

FIGS. 17 to 23 are schematic cross-cross-sectional views illustrating process steps of a method of manufacturing a display device in accordance with an embodiment of the disclosure.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

In the entire specification, in case that an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that in case that a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

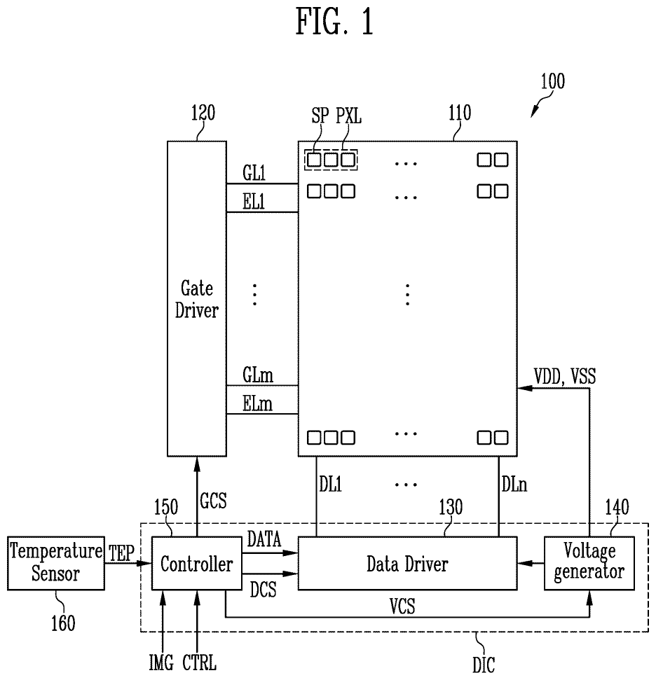

FIG. 1 is a schematic block diagram illustrating an embodiment of a display device of the disclosure.

Referring to FIG. 1, the display device 100 may include a display panel 110, a gate driver 120, a data driver 130, a voltage generator 140, and a controller 150.

The display panel 110 may include sub-pixels SP. The sub-pixels SP may be electrically connected to the gate driver 120 through first to mth gate lines GL1 to GLm. The sub-pixels SP may be electrically connected to the data driver 130 through first to nth data lines DL1 to DLn.

Each of the sub-pixels SP may include at least one light emitting element to generate light. Accordingly, each of the sub-pixels SP may generate light of a specific color such as red, green, blue, cyan, magenta or yellow. Two or more sub-pixels among the sub-pixels SP may constitute one pixel PXL. For example, three sub-pixels SP may constitute one pixel PXL as shown in FIG. 1.

The gate driver 120 may be electrically connected to the sub-pixels SP arranged in a row direction through the first to mth gate lines GL1 to GLm (i.e., m is an integer greater than 1). The gate driver 120 may output gate signals to the first to mth gate lines GL1 to GLm in response to a gate control signal GCS. The gate control signal GCS may include a start signal indicating a start of each frame, a horizontal synchronization signal for outputting gate signals in synchronization with timings at which data signals are applied, and the like.

First to mth light emitting control lines EL1 to ELm (i.e., m is an integer greater than 1) electrically connected to the sub-pixels SP in the row direction may be further provided. The gate driver 120 may include an emission control driver to control the first to mth emission control lines EL1 to ELm, and the emission control driver may operate under the control of the controller 150.

The gate driver 120 may be disposed at one side of the display panel 110. However, embodiments are not limited thereto. For example, the gate driver 120 may be divided into two or more drivers which are physically and/or logically divided, and these drivers may be disposed at a side of the display panel 110 and another side of the display panel 110. As such, in other embodiments, the gate driver 120 may be disposed in various forms at the periphery of the display panel 110.

The data driver 130 may be electrically connected to the sub-pixels SP arranged in a column direction through the first to nth data lines DL1 to DLn (i.e., n is an integer greater than 1). The data driver 130 may receive image data DATA and a data control signal DCS from the controller 150. The data driver 130 may operate in response to the data control signal DCS. The data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. In case that a gate signal is applied to each of the first to mth gate lines GL1 to GLm, data signals corresponding to the image data DATA may be applied to the data lines DL1 to DLm. Accordingly, corresponding sub-pixels SP may generate light corresponding to the data signals. Accordingly, an image may be displayed on the display panel 110.

The gate driver 120 and the data driver 130 may include complementary metal-oxide semiconductor (CMOS) circuit elements.

The voltage generator 140 may operate in response to a voltage control signal VCS from the controller 150. The voltage generator 140 may generate a plurality of voltages and provide the generated voltages to components of the display device 100. For example, the voltage generator 140 may generate a plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In other embodiments, the first power voltage VDD or the second power voltage VSS may be provided by an external device of the display device 100.

The voltage generator 140 may generate various voltages. For example, the voltage generator 140 may generate an initialization voltage applied to the sub-pixels SP. For example, a predetermined reference voltage may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from an external source, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. The controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

The display device 100 may include at least one temperature sensor 160. The temperature sensor 160 may sense a temperature at the periphery thereof and generate temperature data TEP indicating the sensed temperature. The temperature sensor 160 may be disposed adjacent to the display panel 110 and/or the driver integrated circuit DIC.

The controller 150 may receive the temperature data TEP from the temperature sensor 160 and control various operations of the display device 100 in response to the temperature data TEP. The controller 150 may adjust the luminance of an image output from the display panel 110 in response to the temperature data TEP. For example, the controller 150 may control components such as the data driver 130 and/or the voltage generator 140, thereby adjusting data signals and the first and second power voltages VDD and VSS.

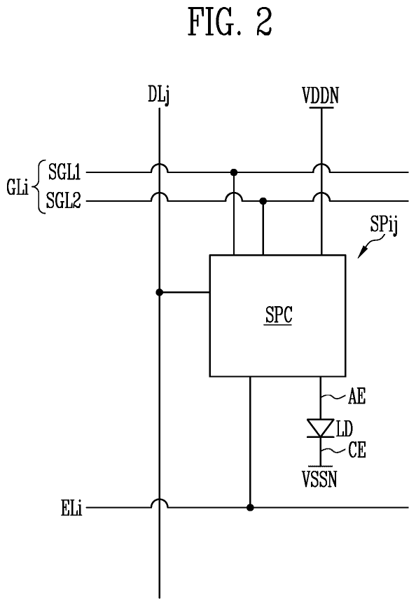

FIG. 2 is a schematic block diagram illustrating an embodiment of any one of the sub-pixels shown in FIG. 1. In FIG. 2, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 1 is illustrated.

Referring to FIG. 2, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be electrically connected to the first power voltage node VDDN through the sub-pixel circuit SPC, and a cathode electrode CE of the light emitting element LD may be electrically connected to the second power voltage node VSSN. For example, the anode electrode AE of the light emitting element LD may be electrically connected to the first power voltage node VDDN through one or more transistors included in the sub-pixel circuit SPC.

The sub-pixel circuit SPC may be electrically connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may control the light emitting element LD according to signals received through these signal lines.

The sub-pixel circuit SPC may operate in response to a gate signal received through the ith gate line GLi. The ith gate line GLi may include one or more sub-gate lines. As shown in FIG. 2, the ith gate line GLi may include first and second sub-gate lines SGL1 and SGL2. The sub-pixel circuit SPC may operate in response to gate signals received through the first and second sub-gate lines SGL1 and SGL2. In case that the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. The ith emission control line ELi may include one or more sub-emission control lines. In case that the ith emission control line ELi includes two or more sub-emission control lines, the sub-pixel circuit SPC may operate in response to emission control signals applied through the corresponding emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

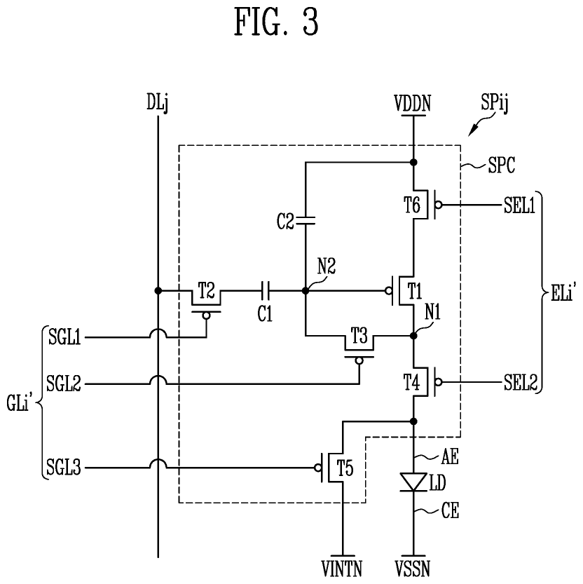

FIG. 3 is a schematic circuit diagram illustrating an embodiment of the sub-pixel shown in FIG. 2.

Referring to FIG. 3, a sub-pixel SPij may include a sub-pixel circuit SPC and a light emitting element LD.

The sub-pixel circuit SPC may be electrically connected to an ith gate line GLi′, an ith emission control line ELi′, and a jth data line DLj. In case that comparing the ith gate line GLi′ with the ith gate line GLi shown in FIG. 2, the ith gate line GLi′ may further include a third sub-gate line SGL3. In case that comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be electrically connected between a first power voltage node VDDN and a first node N1. A gate of the first transistor T1 may be electrically connected to a second node N2, and accordingly, the first transistor T1 may be turned on according to a voltage level of the second node N2. The first transistor T1 may be designated as a driving transistor.

The second transistor T2 may be electrically connected between the jth data line DLj and the second node N2. A gate of the second transistor T2 may be electrically connected to a first sub-gate line SGL1 of the ith gate line GLi′, and accordingly, the second transistor T2 may be turned on in response to a gate signal of the first sub-gate line SGL1. The second transistor T2 may be designated as a switching transistor.

The third transistor T3 may be electrically connected between the first node N1 and the second node N2. A gate of the third transistor T3 may be electrically connected to a second sub-gate line SGL2 of the ith gate line GLi′, and accordingly, the third transistor T3 may be turned on in response to a gate signal of the second sub-gate line SGL2.

The fourth transistor T4 may be electrically connected between the first node N1 and an anode electrode AE of the light emitting element LD. A gate of the fourth transistor T4 may be electrically connected to the second sub-emission control line SEL2 of the ith emission line ELi′, and accordingly, the fourth transistor T4 may be turned on in response to an emission control signal of the second sub-emission control line SEL2.

The fifth transistor T5 may be electrically connected between an anode electrode AE of the light emitting element LD and an initialization voltage node VINTN. The initialization voltage node VINTN may transfer an initialization voltage. The initialization voltage may be provided by the voltage generator 140 shown in FIG. 1. In other embodiments, the initialization voltage may be provided by an external device of the display device 100. A gate of the fifth transistor T5 may be electrically connected to the third sub-gate line SGL3 of the ith gate line GLi′, and accordingly, the fifth transistor T5 may be turned on in response to a gate signal of the third sub-gate line SGL3.

The sixth transistor T6 may be electrically connected between the first power voltage node VDDN and the first transistor T1. A gate of the sixth transistor T6 may be electrically connected to the first sub-emission control line SEL1 of the ith emission line ELi′, and accordingly, the sixth transistor T6 may be turned on in response to an emission control signal of the first sub-emission control line SEL1.

The first capacitor C1 may be electrically connected between the second transistor T2 and the second node N2. The second capacitor C2 may be electrically connected between the first power voltage node VDDN and the second node N2.

The sub-pixel circuit SPC may include the first to sixth transistors T1 to T6 and the first and second capacitors C1 and C2. However, embodiments are not limited thereto. The sub-pixel circuit SPC may be implemented as any one of various types of circuits each including a plurality of transistors and one or more capacitors. For example, the sub-pixel circuit SPC may include two transistors and one capacitor. In accordance with embodiments of the sub-pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments are not limited thereto. For example, at least one of the first to sixth transistors T1 to T6 may be replaced with an N-type transistor.

The first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, a cathode electrode CE, and a light emitting layer. The light emitting layer may be disposed between the anode electrode AE and the cathode electrode CE. After a data signal transferred through the jth data line DLj is reflected on a voltage of the second node N2, the fourth and sixth transistors T4 and T6 may be turned on in case that the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

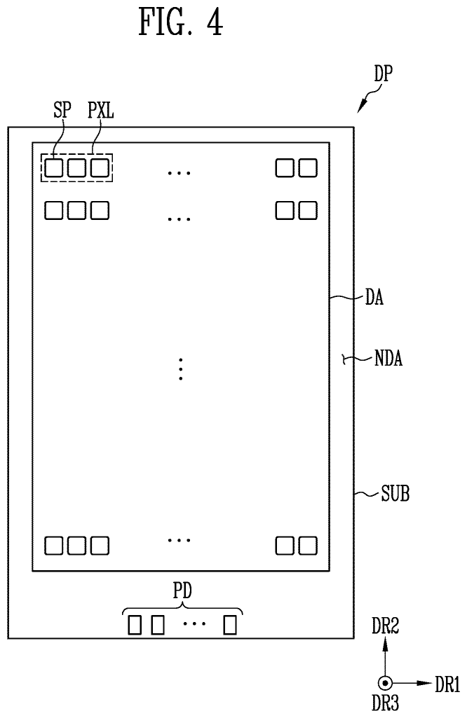

FIG. 4 is a schematic plan view illustrating an embodiment of the display panel shown in FIG. 1.

Referring to FIG. 4, a display device DP may include a display area DA and a non-display area NDA. The display panel DP may display an image through the display area DA. The non-display area NDA may be disposed at the periphery of the display area DA. For example, the non-display area NDA may be disposed to surround the display area DA.

The display panel DP may include a substrate SUB, sub-pixels SP, and pads PD. In case that the display panel DP is used as a display screen of a Head Mounted Display (HMD), a Virtual Reality (VR) device, a Mixed Reality (MR) device, an Augmented Reality (AR) device, and the like, the display panel DP may be positioned close to eyes of a user. The sub-pixels SP having a relatively high degree of integration may be required. To increase the degree of integration of the sub-pixels SP, the substrate SUB may be provided as a silicon substrate. The sub-pixels SP and/or the display panel DP may be disposed on the substrate SUB as the silicon substrate. The display device 100 (see FIG. 1) including the display panel DP disposed on the substrate SUB as the silicon substrate may be designated as an OLED on Silicon (OLEDOS) display device.

The sub-pixels SP may be disposed in the display area DA on the substrate SUB. The sub-pixels SP may be arranged in a matrix form along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be disposed in a Pentile® form. The first direction DR1 may be a row direction, and the second direction DR2 may be a column direction.

Two or more sub-pixels among the sub-pixels SP may constitute one pixel PXL.

A component for controlling the sub-pixels SP may be disposed in the non-display area NDA on the substrate SUB. For example, lines electrically connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. The gate driver 120 shown in FIG. 1 is mounted on the display panel DP, and may be disposed in the non-display area NDA. In other embodiments, the gate driver 120 may be implemented as an integrated circuit distinguished from the display panel DP. The temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through the lines. For example, the pads PD may be electrically connected to the sub-pixels SP through the first to nth data lines DL1 to DLn.

The pads PD may interface the display panel DP with other components of the display device 100 (see FIG. 1). Voltages and signals, which are necessary for operations of components included in the display panel DP, may be provided from the driver integrated circuit DIC shown in FIG. 1 through the pads PD. For example, the first to nth data lines DL1 to DLn may be electrically connected to the driver integrated circuit DIC through the pads PD. For example, the first and second power voltages VDD and VSS may be received from the driver integrated circuit DIC through the pads PD. In case that the gate driver 120 is mounted in the display panel DP, the gate control signal GCS may be transmitted from the driver integrated circuit DIC to the gate driver 120 through the pads PD.

A circuit board may be electrically connected to the pads PD using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

The display area DA may have various shapes. The display area DA may have a closed-loop shape including linear sides and/or curved sides. For example, the display area DA may have shapes such as a polygon, a circle, a semicircle, and an ellipse.

The display panel DP may have a flat display surface. In other embodiments, the display panel DP may at least partially have a round display surface. The display panel DP may be bendable, foldable or rollable. The display panel DP and/or the substrate SUB may include materials having flexibility.

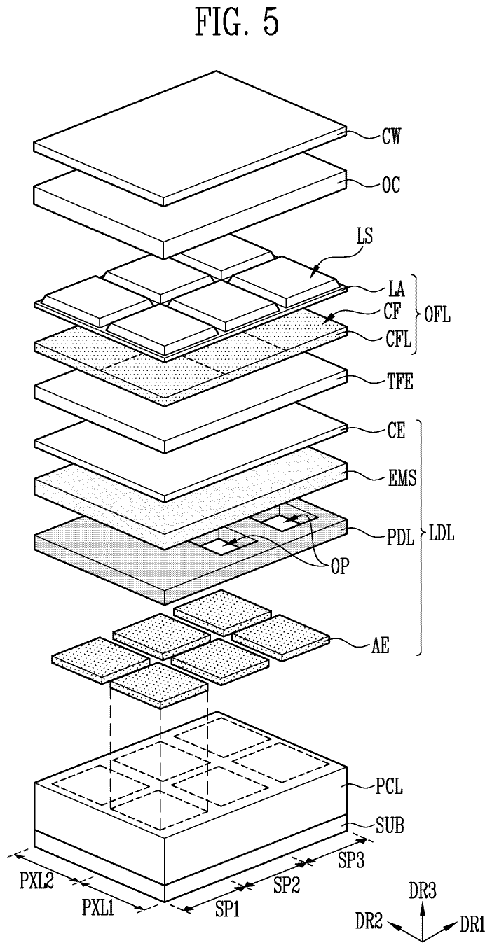

FIG. 5 is an exploded schematic perspective view illustrating a portion of the display panel shown in FIG. 4. In FIG. 5, for clear and brief description, a portion of the display panel DP, which corresponds to two pixels among the pixels PXL shown in FIG. 4, may be schematically illustrated. A portion of the display panel DP, which corresponds to the other pixels, may also be configured identically.

Referring to FIGS. 4 and 5, each of first and second pixels PXL1 and PXL2 may include first to third sub-pixels SP1, SP2, and SP3. However, embodiments are not limited thereto. For example, each of the first and second pixels PXL1 and PXL2 may include four sub-pixels or include two sub-pixels.

In FIG. 5, it may be illustrated that each of the first to third sub-pixels SP1, SP2, and SP3 may have quadrangular shapes in case that viewed in a third direction DR3 intersecting the first and second directions DR1 and DR2 (e.g., in a plan view), and have equal size. However, embodiments are not limited thereto. The first to third sub-pixels SP1, SP2, and SP3 may be modified to have various shapes.

The display panel DP may include a substrate SUB, a pixel circuit layer PCL, a light emitting element layer LDL, an encapsulation layer TFE, an optical functional layer OFL, an overcoat layer OC, and a cover window CW.

The substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like. The conductive patterns may include copper, but embodiments are not limited thereto.

The circuit elements may include a sub-pixel circuit SPC (see FIG. 2) of each of the first to third sub-pixels SP1 to SP3. The sub-pixel circuit SPC may include transistors and one or more capacitors. Each transistor may include a semiconductor portion including a source region, a drain region, and a channel region, and a gate electrode overlapping with the semiconductor portion. In case that the substrate SUB is provided as a silicon substrate, the semiconductor portion may be included in the substrate SUB, and the gate electrode may be included as a conductive pattern of the pixel circuit layer PCL in the pixel circuit layer PCL. In case that the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other in the third direction DR3 (e.g., thickness direction) with an insulating layer interposed therebetween.

The lines of the pixel circuit layer PCL may include signal lines, e.g., a gate line, an emission control line, a data line, and the like, which are electrically connected to each of the first to third sub-pixels SP1, SP2, and SP3. The lines may further include a line electrically connected to the first power voltage node VDDN shown in FIG. 2. The lines may further include a line electrically connected to the second power voltage node VSSN shown in FIG. 2.

The light emitting element layer LDL may include an anode electrodes AE, a pixel defining layer PDL, a light emitting structure (or light emitting member) EMS, and a cathode electrode CE. For example, the anode electrodes AE, the pixel defining layer PDL, the light emitting structure EMS, and the cathode electrode CE may be sequentially stacked in the third direction DR3.

The anode electrodes AE may be disposed on the pixel circuit layer PCL. The anode electrodes AE may be in contact with the circuit elements of the pixel circuit layer PCL. The anode electrodes AE may include an opaque conductive material capable of reflecting light, but embodiments are not limited thereto.

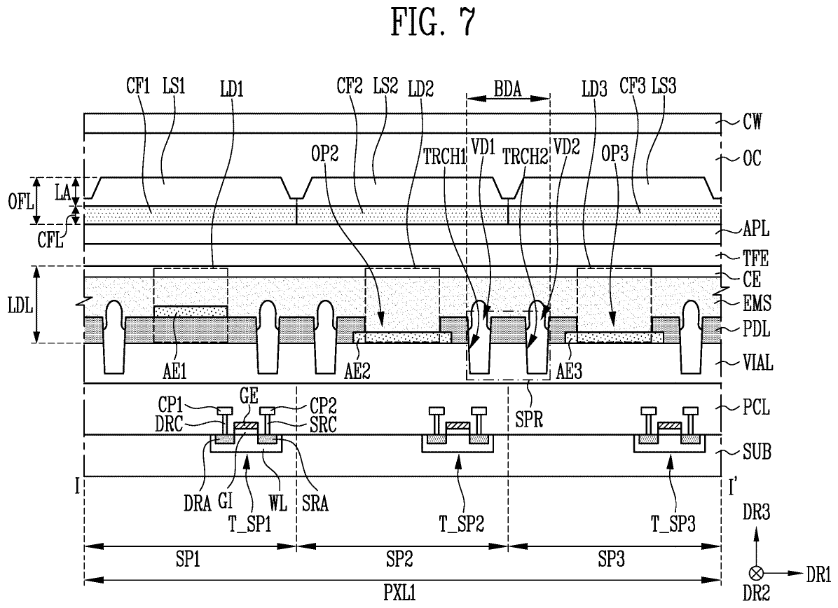

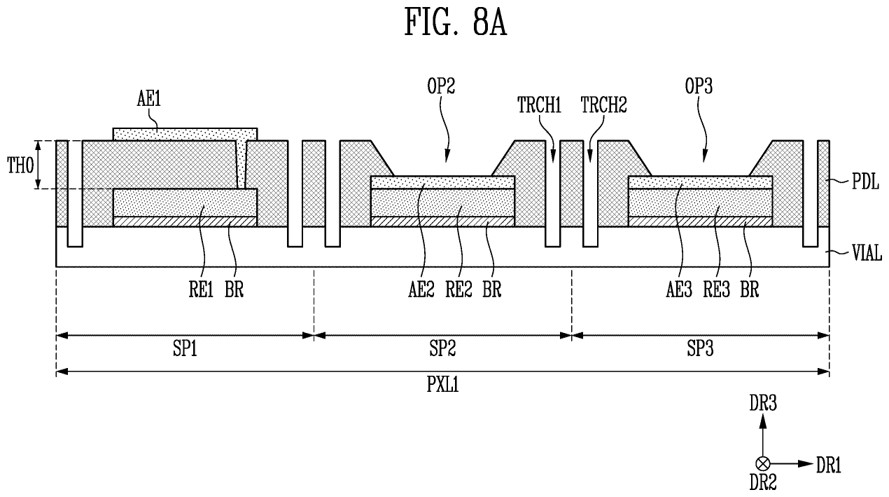

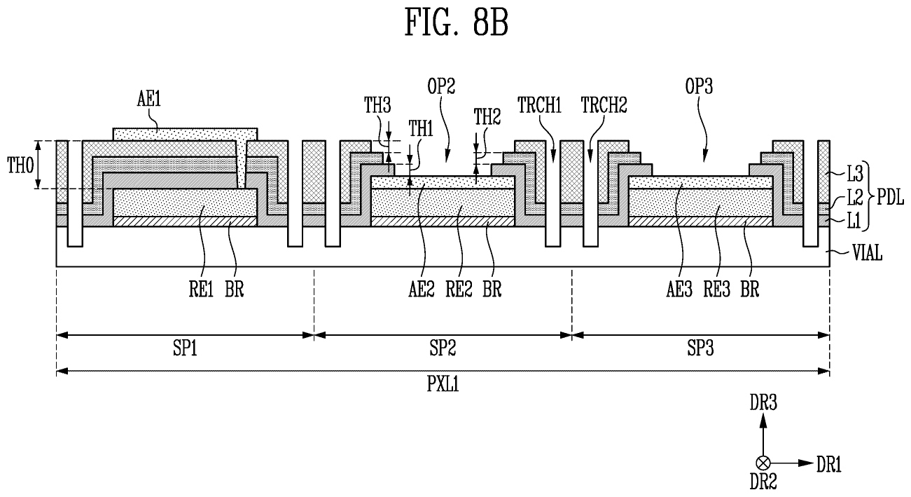

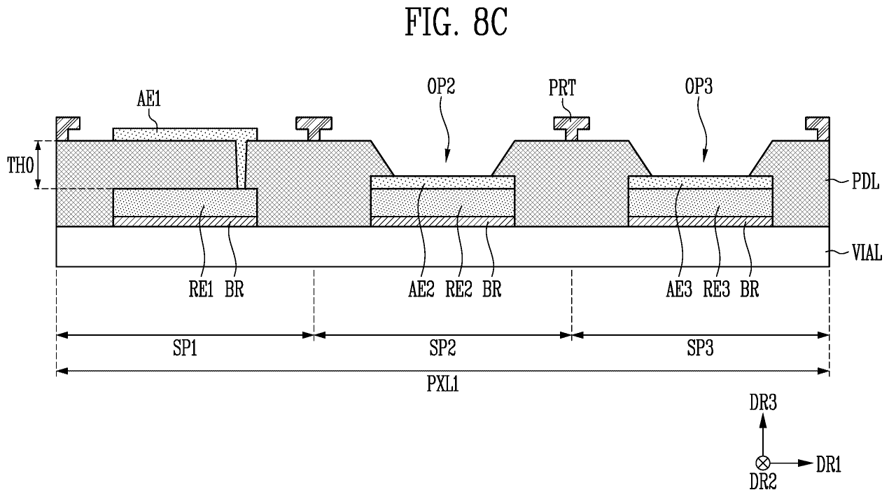

The pixel defining layer PDL may be disposed on the anode electrodes AE. The pixel defining layer PDL may include an opening OP exposing a portion of each of the anode electrodes AE. The opening OP of the pixel defining layer PDL may be defined as an emission area corresponding to each of the first to third sub-pixels SP1, SP2, and SP3. In FIG. 5, the pixel defining layer PDL may be disposed on the anode electrodes AE. However, the disclosure is not limited thereto. For example, some of the anode electrodes AE may be disposed on the pixel defining layer PDL, and the pixel defining layer PDL may not include any openings corresponding to the some of the anode electrodes AE (see FIGS. 7 and 8A to 8C).

The pixel defining layer PDL may include an inorganic material. The pixel defining layer PDL may include a plurality of stacked inorganic layers. For example, the pixel defining layer PDL may include silicon oxide (SiOₓ) and silicon nitride (SiNₓ). In other embodiments, the pixel defining layer PDL may include an organic material. However, the material of the pixel defining layer PDL is not limited thereto.

The light emitting structure EMS may be disposed on the anode electrodes AE exposed by the openings OP of the pixel defining layer PDL. The light emitting structure EMS may include a light emitting layer to generate light, an electron transport layer to transport electrons, a hole transport layer to transport holes, and the like.

The light emitting structure EMS fills the opening OP of the pixel defining layer PDL, and may be entirely disposed on the top of the pixel defining layer PDL. For example, the light emitting structure EMS may extend throughout the first to third sub-pixels SP1, SP2, and SP3. At least some of the layers in the light emitting structure EMS may be cut or bent at boundaries between the first to third sub-pixels SP1, SP2, and SP3. However, embodiments are not limited thereto. For example, portions of the light emitting structure EMS, which correspond to the first to third sub-pixels SP1, SP2, and SP3, may be separated from each other, and each of the portions may be disposed in the opening OP of the pixel defining layer PDL.

The cathode electrode CE may be disposed on the light emitting structure EMS. The cathode electrode CE may extend throughout the first to third sub-pixels SP1, SP2, and SP3. The cathode electrode CE may be provided as a common electrode for the first to third sub-pixels SP1, SP2, and SP3.

The cathode electrode CE may be a thin metal layer having a thickness to a degree to which light emitted from the light emitting structure EMS can be transmitted therethrough. The cathode electrode CE may be formed of a metal material to have a relatively thin thickness or be formed of a transparent conductive material. The cathode electrode CE may include at least one of various transparent conductive materials including indium tin oxide, indium zinc oxide, indium tin zinc oxide, aluminum zinc oxide, gallium zinc oxide, zinc tin oxide, and gallium tin oxide. In other embodiments, the cathode electrode CE may include at least one of silver (Ag), magnesium (Mg), and mixtures thereof. However, the material of the cathode electrode CE is not limited thereto.

It may be understood that any one of the anode electrodes AE, a portion of the light emitting structure EMS, which overlaps therewith, and a portion of the cathode electrode CE, which overlaps therewith, constitute one light emitting element LD (see FIG. 2). For example, each of light emitting elements of the first to third sub-pixels SP1, SP2, and SP3 may include one anode electrode AE, a portion of the light emitting structure EMS, which overlaps therewith, and a portion of the cathode electrode CE, which overlaps therewith. In each of the first to third sub-pixels SP1, SP2, and SP3, holes injected from the anode electrode AE and electrons injected from the cathode electrode CE may be transported into a light emitting layer of the light emitting structure EMS to form excitons, and light may be generated in case that the excitons are changed from an excited state to a ground state. A luminance of the light may be determined according to an amount of current flowing through the light emitting layer. A wavelength band of the generated light may be determined according to a configuration of the light emitting layer.

The encapsulation layer TFE may be disposed on the cathode electrode CE. The encapsulation layer TFE may cover the light emitting element layer LDL and/or the pixel circuit layer PCL. The encapsulation layer TFE may prevent oxygen and/or moisture from infiltrating into the light emitting element layer LDL. The encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

To improve encapsulation efficiency of the encapsulation layer TFE, the encapsulation layer TFE may further include a thin film including aluminum oxide (AlOₓ). The thin film including the aluminum oxide may be located on a top surface of the encapsulation layer TFE, which faces the optical functional layer OFL, and/or a bottom surface of the encapsulation layer TFE, which faces the light emitting element layer LDL.

The thin film including the aluminum oxide may be formed through an Atomic Layer Deposition (ALD) process. However, embodiments are not limited thereto. The encapsulation layer TFE may further include a thin film formed of at least one of various materials suitable for the improvement of the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter out light emitted from the light emitting structure EMS, thereby selectively outputting light of a wavelength band or a color, which corresponds to each sub-pixel SP. The color filter layer CFL may include color filters CF respectively corresponding to the first to third sub-pixels SP1, SP2, and SP3. Each of the color filters CF may allow light having a wavelength band corresponding to a corresponding sub-pixel to pass therethrough. For example, a color filter overlapping the first sub-pixel SP1 may allow light of a red color to pass therethrough, a color filter overlapping the second sub-pixel SP2 may allow light of a green color to pass therethrough, and a color filter overlapping the third sub-pixel SP3 may allow light of a blue color to pass therethrough. According to light emitted from the light emitting structure EMS in each sub-pixel SP, at least some of the color filters CF may be omitted.

The lens array LA may be disposed on the color filter layer CFL. The lens array LA may include lenses LS respectively overlapping the first to third sub-pixels SP1, SP2, and SP3. Each of the lenses LS may output light emitted from the light emitting structure EMS along an intended path, thereby improving light output efficiency. The lens array LA may have a relatively high refractive index. For example, the lens array LA may have a refractive index higher than a refractive index of the overcoat layer OC. The lenses LS may include an organic material. The lenses LS may include an acryl-based material. However, the material of the lenses LS is not limited thereto.

As compared to the opening OP of the pixel defining layer PDL, at least some of the color filters CF of the color filter layer CFL and at least some of the lenses LS of the lens array LA may be shifted in a direction parallel to a plane defined by the first and second directions DR1 and DR2. In a central area of the display area DA, the center of a color filter and the center of a lens may be aligned or overlap the center of a corresponding opening OP of the pixel defining layer PDL. For example, in the central area of the display area DA, the opening OP of the pixel defining layer PDL may completely overlap the corresponding color filter of the color filter layer CFL and the corresponding lens of the lens array LA. In an area of the display area DA, which is adjacent to the non-display area NDA, the center of a color filter and the center of a lens may be shifted in a planar direction from the center of an opening OP of the pixel defining layer PDL. For example, in the area of the display area DA, which is adjacent to the non-display area NDA, the opening OP of the pixel defining layer PDL may partially overlap the corresponding color filter of the color filter layer CFL and the corresponding lens of the lens array LA. Accordingly, in the center of the display area DA, light emitted from the light emitting structure EMS can be output in a normal direction of the display surface. At an outer portion of the display area DA, light emitted from the light emitting structure EMS can be output in a direction inclined by a predetermined angle with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

The cover window CW may be disposed on the overcoat layer OC. The cover window CW may protect lower layers thereof. The cover window CW may have a refractive index higher than the refractive index of the overcoat layer OC. The cover window CW may include glass, but embodiments are not limited thereto. For example, the cover window CW may be an encapsulation glass to protect components disposed thereunder. In other embodiments, the cover window CW may be omitted.

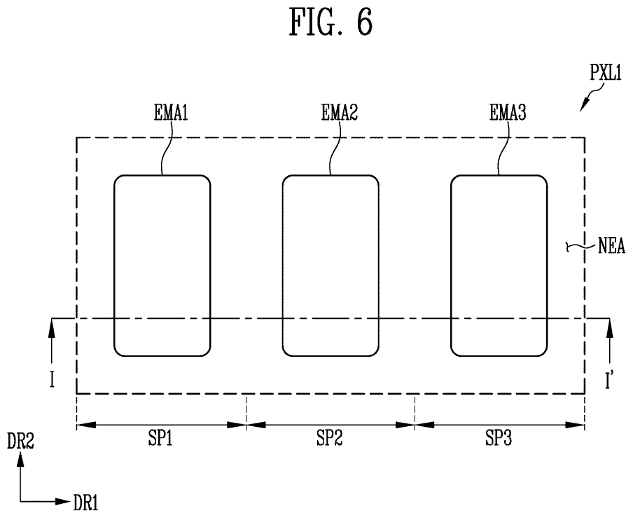

FIG. 6 is a schematic plan view illustrating an embodiment of any one of the pixels shown in FIG. 5. In FIG. 6, for clear and brief description, the first pixel PXL1 among the first and second pixels PXL1 and PXL2 shown in FIG. 5 is schematically illustrated. The other pixels may be configured identically to the first pixel PXL1.

Referring to FIGS. 5 and 6, the first pixel PXL1 may include first to third sub-pixels SP1, SP2, and SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a portion of the light emitting structure EMS (see FIG. 5), which overlaps the first sub-pixel SP1 in the third direction DR3. The second emission area EMA2 may be an area in which light is emitted from a portion of the light emitting structure EMS, which overlaps the second sub-pixel SP2 in the third direction DR3. The third emission area EMA3 may be an area in which light is emitted from a portion of the light emitting structure EMS, which overlaps the third sub-pixel SP3 in the third direction DR3. As described with reference to FIG. 5, the first to third emission areas EMA1, EMA2, and EMA3 may be defined as openings OP of the pixel defining layer PDL, which respectively correspond to the first to third sub-pixels SP1, SP2, and SP3. Although will be described later with reference to FIG. 7, an emission area of a sub-pixel may correspond to an anode electrode in case that there exists no opening of the pixel defining layer PDL, which overlaps the sub-pixel in the third direction DR3.

FIG. 7 is a schematic cross-sectional view taken along line I-I′ shown in FIG. 6. FIGS. 8A, 8B, and 8C are enlarged schematic cross-sectional views illustrating a portion of a light emitting element layer shown in FIG. 7.

Referring to FIGS. 7 and 8A to 8C, a substrate SUB and a pixel circuit layer PCL disposed on the substrate SUB may be provided.

The substrate SUB may include a silicon wafer substrate formed using a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of first to third sub-pixels SP1, SP2, and SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of transistors included in a sub-pixel circuit SPC (see FIG. 2) of the first sub-pixel SP1, the transistor T_SP2 of the second sub-pixel SP2 may be any one of transistors included in a sub-pixel circuit SPC of the second sub-pixel SP2, and the transistor T_SP3 of the third sub-pixel SP3 may be any one of transistors included in a sub-pixel circuit SPC of the third sub-pixel SP3. In FIG. 7, for clear and brief description, one of the transistors of each sub-pixel is illustrated, and the other circuit elements are omitted.

The transistors T_SP1 of the first sub-pixel SP1 may include a source region SRA, a drain region DRA, and a gate electrode GE interposed between the source region SRA and the drain region DRA.

The source region SRA and the drain region DRA may be disposed in the substrate SUB. A well WL formed through an ion implantation process may be disposed in the substrate SUB, and the source region SRA and the drain region DRA may be disposed in the well WL to be spaced apart from each other. A region between the source region SRA and the drain region DRA in the well WL may be defined as a channel region.

The gate electrode GE may overlap the channel region between the source region SRA and the drain region DRA in the third direction DR3, and be disposed in the pixel circuit layer PCL. The gate electrode GE may be spaced apart from the well WL or the channel region by an insulating material such as a gate insulating layer GI. The gate electrode GE may include a conductive material.

A plurality of layers included in the pixel circuit layer PCL may include insulating layers and conductive patterns disposed between the insulating layers, and the conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

As the gate electrode GE and the first and second conductive patterns CP1 and CP2 are electrically connected to other circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured identically to the transistor T_SP1 of the first sub-pixel SP1.

As such, the substrate SUB and/or the pixel circuit layer PCL may include circuit elements of each of the first to third sub-pixels SP1, SP2, and SP3.

A via layer VIAL may be disposed on the pixel circuit layer PCL. The via layer VIAL covers the pixel circuit layer PCL, and may have an entirely flat surface. The via layer VIAL may planarize step differences on the pixel circuit layer PCL. The via layer VIAL may include at least one of silicon oxide (SiOₓ), silicon nitride (SiNₓ), and silicon carbon nitride (SiCN), but embodiments are not limited thereto.

Referring to FIGS. 7 and 8A to 8C, a light emitting element layer LDL may be disposed on the via layer VIAL. The light emitting element layer LDL may include a barrier layer BR, a reflective electrode, an anode electrode, a pixel defining layer PDL, a light emitting structure EMS, and/or a cathode electrode CE. The reflective electrode may include first to third reflective electrodes RE1, RE2, and RE3. The anode electrode may include first to third anode electrodes AE1, AE2, and AE3. Between the via layer VIAL and the light emitting structure EMS, the first sub-pixel SP1 may have a stacked structure different from a stacked structure of the second sub-pixel SP2. The third sub-pixel SP3 and the second sub-pixel SP2 may have a same stacked structure.

Referring to FIGS. 8A to 8C, the barrier layer BR may be disposed in each of the first to third sub-pixels SP1, SP2, and SP3. The barrier layer BR may be disposed on the via layer VIAL. The barrier layer BR may be disposed on the via layer VIAL (or a base layer). The barrier layer BR may improve electrical connection characteristics between the first to third reflective electrodes RE1, RE2, and RE3 and a circuit element of the pixel circuit layer PCL. The barrier layer BR may have a multi-layer structure. The multi-layer structure of the barrier layer BR may include titanium (Ti), titanium nitride (TIN), tantalum nitride (TaN), and the like, but the disclosure is not necessarily limited thereto. The barrier layer BR of each of the first to third sub-pixels SP1, SP2, and SP3 may be in contact with the circuit element disposed in the pixel circuit layer PCL through a via penetrating the via layer VIAL.

The first to third reflective electrodes RE1, RE2, and RE3 may be disposed on the barrier layer BR. The first to third reflective electrodes RE1, RE2, and RE3 may be disposed in the first to third sub-pixels SP1, SP2, and SP3, respectively.

The first to third reflective electrodes RE1, RE2, and RE3 may serve as full mirrors which reflect light emitted from the light emitting structure EMS toward a display surface (or a cover window CW as shown in FIG. 7). The first to third reflective electrodes RE1, RE2, and RE3 may include a metal material suitable for reflecting light. The first to third reflective electrodes RE1, RE2, and RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments are not limited thereto.

The first to third anode electrodes AE1, AE2, and AE3 (or first electrodes) may be disposed on the first to third reflective electrodes RE1, RE2, and RE3. The first to third anode electrodes AE1, AE2, and AE3 may be disposed in the first to third sub-pixels SP1, SP2, and SP3, respectively.

The first to third anode electrodes AE1, AE2, and AE3 may have shapes identical or similar to shapes of the first to third emission areas EMA1, EMA2, and EMA3 shown in FIG. 6 in case that viewed in the third direction DR3 (e.g., in a plan view). For example, the first anode electrode AE1 and the first emission area EMA1 may have a same shape, and the second and third anode electrodes AE2 and AE3 and the second and third emission areas EMA2 and EMA3 may have same shapes, respectively.

The first to third anode electrodes AE1, AE2, and AE3 may be electrically connected to the first to third reflective electrodes RE1, RE2, and RE3, respectively. For example, the first anode electrode AE1 may be electrically connected to the first reflective electrode RE1 through a contact hole penetrating the pixel defining layer PDL. The second anode electrode AE2 may be disposed on the second reflective electrode RE2, to be in direct contact with a top surface of the second reflective electrode RE2. The third anode electrode AE3 may be disposed on the third reflective electrode RE3, to be in direct contact with a top surface of the third reflective electrode RE3.

The first to third anode electrodes AE1, AE2, and AE3 may include titanium (Ti), titanium nitride (TIN), tantalum nitride (TaN), and the like. For example, the first to third anode electrodes AE1, AE2, and AE3 may include titanium nitride. However, the material of the first to third anode electrodes AE1, AE2, and AE3 is not limited thereto. For example, the first to third anode electrodes AE1, AE2, and AE3 may include at least one of transparent conductive materials such as indium tin oxide (ITO), indium zinc oxide (IZO), zinc oxide (ZnO), indium gallium zinc oxide (IGZO), and indium tin zinc oxide (ITZO). The first anode electrode AE1 may include a same material as the second and third anode electrodes AE2 and AE3 or include a material different from the second and third anode electrodes AE2 and AE3.

Each of the first to third anode electrodes AE1, AE2, and AE3 may be formed as a single layer. However, the disclosure is not limited thereto. For example, each of the first to third anode electrodes AE1, AE2, and AE3 may have a multi-layer structure.

A thickness of each of the first to third anode electrodes AE1, AE2, and AE3 in the third direction DR3 may be in a range of about 50 Å to about 100 Å. For example, the thickness of each of the first to third anode electrodes AE1, AE2, and AE3 in the third direction DR3 may be about 60 Å, but the disclosure is not limited thereto.

The pixel defining layer PDL may be disposed on the first to third reflective electrodes RE1, RE2, and RE3. The pixel defining layer PDL may be disposed on the second and third anode electrodes AE2 and AE3. The pixel defining layer PDL may be disposed between the first reflective electrode RE1 and the first anode electrode AE1.

The pixel defining layer PDL may include second and third openings OP2 and OP3 respectively exposing portions of the second and third anode electrodes AE2 and AE3. The pixel defining layer PDL may include no opening overlapping the first anode electrode AE1. The second and third openings OP2 and OP3 of the pixel defining layer PDL may have a same depth. The second opening OP2 of the pixel defining layer PDL may define the second emission area EMA2 (see FIG. 6) of the second sub-pixel SP2, and the third opening OP3 of the pixel defining layer PDL may define the third emission area EMA3 (see FIG. 6) of the third sub-pixel SP3. The first emission area EMA1 (see FIG. 6) of the first sub-pixel SP1 may be defined by the first anode electrode AE1. Since the emission areas EMA2 and EMA3 (see FIG. 6) of the second and third sub-pixels SP2 and SP3 are defined by the pixel defining layer PDL, there is no particular problem even in case that the emission area EMA1 of the first sub-pixel SP1 as the other of the first to third emission areas EMA1, EMA2, and EMA3 is not defined by the pixel defining layer PDL.

The pixel defining layer PDL may include at least one of silicon oxide (SiOₓ) and silicon nitride (SiNₓ). For example, the pixel defining layer PDL may include silica (SiO₂). The pixel defining layer PDL disposed between the first reflective electrode RE1 and the first anode electrode AE1 may function to adjust a resonance distance such that light can be output in an optimum resonance condition. For example, the first to third reflective electrodes RE1, RE2, and RE3 may serve full mirrors, and the cathode electrode CE may serve as a half mirror. Light emitted from a light emitting layer of the light emitting structure EMS may be amplified by at least partially reciprocating between each of the first to third reflective electrodes RE1, RE2, and RE3 and the cathode electrode CE, and the amplified light may be output through the cathode electrode CE. A distance between each of the first to third reflective electrodes RE1, RE2, and RE3 and the cathode electrode CE may be understood as a resonance distance of light emitted from the light emitting layer of the corresponding light emitting structure EMS.

For example, the first sub-pixel SP1 may have a resonance distance longer than a resonance distance of each of the second sub-pixel SP2 and the third sub-pixel SP3. The second sub-pixel SP2 and the third sub-pixel SP3 may have resonance distances substantially equal or similar to each other. Such an adjusted resonance distance enables light in a specific wavelength range to be effectively and efficiently amplified in each of the first to third sub-pixels SP1, SP2, and SP3. Accordingly, since each of the first to third sub-pixels SP1, SP2, and SP3 effectively and efficiently outputs light in a corresponding wavelength band, the luminance of the display device may be improved.

A thickness of the pixel defining layer PDL on the first reflective electrode RE1 may be about ¼ of the wavelength band of light which the first sub-pixel SP1 emits to the outside. For example, in case that the first sub-pixel SP1 emits light of a red color (e.g., light in a wavelength band of about 600 nm to about 750 nm), a thickness TH0 of the pixel defining layer PDL in the third direction DR3 disposed on the first reflective electrode RE1 may be in a range of about 1500 Å to about 1900 Å. A distance between the first reflective electrode RE1 and the first anode electrode AE1 may be in a range of about 1500 Å to about 1900 Å. For example, the distance between the first reflective electrode RE1 and the first anode electrode AE1 may be about 1700 Å. In case that the distance between the first reflective electrode RE1 and the first anode electrode AE1 is beyond the range of about 1500 Å to about 1900 Å, the light output efficiency (or luminance) of the light of the red color may be lowered while the light is absorbed or disappears between the first reflective electrode RE1 and the first anode electrode AE1.

The pixel defining layer PDL may include a single inorganic insulating layer or a plurality of inorganic insulating layers. An example will be described with reference to FIG. 8B. The pixel defining layer PDL may include a first layer L1, a second layer L2 disposed on the first layer L1, and a third layer L3 disposed on the second layer L2. A thickness TH1 of the first layer L1 in the third direction DR3 may be equal to a thickness TH2 of the second layer L2 in the third direction DR3. A thickness TH3 of the third layer L3 in the third direction DR3 may be different from the thickness TH1 of the first layer L1 and the thickness TH2 of the second layer L2 in the third direction DR3. For example, the thickness TH3 of the third layer L3 in the third direction DR3 may be greater than the thickness TH1 of the first layer L1 and the thickness TH2 of the second layer L2 in the third direction DR3. For example, each of the thickness of the first layer L1 in the third direction DR3 and the thickness TH2 of the second layer L2 in the third direction DR3 may be about 500 Å, and the thickness TH3 of the third layer L3 in the third direction DR3 may be about 700 Å.

Each of the first layer L1, the second layer L2, and the third layer L3 may include at least one of silicon oxide (SiOₓ) and silicon nitride (SiNₓ). For example, the first layer L1 may be formed of silicon nitride (SiNₓ), the second layer L2 may be formed of silicon oxide (SiOₓ), and the third layer L3 may be formed of silicon nitride (SiNₓ). However, the disclosure is not necessarily limited thereto.

A separator SPR may be provided in each of boundary areas BDA between the first sub-pixel SP1 and the second sub-pixel SP2, between the second sub-pixel SP2 and the third sub-pixel SP3, and between the first sub-pixel SP1 and the third sub-pixel SP3. The separator SPR may cause a discontinuity to be formed in the light emitting structure EMS in the boundary area BDA. For example, the light emitting structure EMS may be cut or bent by the separator SPR in the boundary area BDA.

The separator SPR may be provided in or on the pixel defining layer PDL. The pixel defining layer PDL may include one or more trenches TRCH1 and TRCH2 as the separator SPR. As shown in FIG. 7, the one or more trenches TRCH1 and TRCH2 may penetrate the pixel defining layer PDL, and partially penetrate an upper portion of the via layer VIAL.

In FIGS. 7 and 8A, two trenches TRCH1 and TRCH2 may be provided in the boundary area BDA. However, embodiments are not limited thereto. For example, the pixel defining layer PDL may include one trench in the boundary area BDA. For example, the pixel defining layer PDL may include three or more trenches in the boundary area BDA.

Due to first and second trenches TRCH1 and TRCH2, discontinuities such as a first void VD1 and a second void VD2 may be formed in the light emitting structure EMS in the boundary area BDA. Some of a plurality of layers stacked in the light emitting structure EMS may be cut or bent by the first and second voids VD1 and VD2. For example, at least one charge generation layer included in the light emitting structure EMS may be cut by the first and second voids VD1 and VD2. Due to the first and second trenches TRCH1 and TRCH2, portions of the light emitting structure EMS, included in the first to third sub-pixels SP1, SP2, and SP3, may be at least partially separated from each other.

In FIG. 7, the first and second voids VD1 and VD2 may be formed in the light emitting structure EMS in the boundary area BDA. However, this is merely illustrative, and embodiments are not limited thereto. For example, a concave-shaped valley may be formed in the light emitting structure EMS in the boundary area BDA. The discontinuities formed in the light emitting structure EMS may be variously changed according to shapes of the first and second trenches TRCH1 and TRCH2.

The light emitting structure EMS may be formed through a process such as vacuum deposition or inkjet printing. The same materials as the light emitting structure EMS may be located on bottom surfaces adjacent to the via layer VIAL among the first and second trenches TRCH1 and TRCH2.

The separator SPR may be variously modified such that the light emitting structure EMS can have a discontinuity in the boundary area BDA. As depicted in FIG. 8C, a protrusion pattern PRT including inorganic insulating patterns additionally stacked on the pixel defining layer PDL may be provided in the boundary area BDA without the first and second trenches TRCH1 and TRCH2 in the boundary area BDA. A width of an inorganic insulating pattern at an uppermost portion among the additionally stacked inorganic insulating patterns may be greater than a width of an inorganic insulating pattern disposed immediately under the inorganic insulating pattern at the uppermost portion. For example, in the boundary area BDA, first to third inorganic insulating patterns are sequentially stacked from the pixel defining layer PDL, and the third inorganic insulating pattern at the uppermost portion may have a width greater than a width of the second inorganic insulating layer. For example, the protrusion pattern PRT (or the pixel defining layer PDL) may have a section having a “T” shape or an “I” shape in the boundary area BDA. According to the shape of the protrusion pattern PRT (or the pixel defining layer PDL), multiple layers included in the light emitting structure EMS may be partially cut or bent in the boundary area BDA.

The light emitting structure EMS may be disposed on the anode electrodes AE and/or the pixel defining layer PDL. The light emitting structure EMS may be disposed on the anode electrodes AE exposed by the openings OP of the pixel defining layer PDL. The light emitting structure EMS fills the openings OP of the pixel defining layer PDL, and may be entirely disposed throughout the first to third sub-pixels SP1, SP2, and SP3. As described above, the light emitting structure EMS may be at least partially cut or bent by the separator SPR in the boundary area BDA. Accordingly, in an operation of the display panel DP, a current leaked from each of the first to third sub-pixels SP1, SP2, and SP3 to a sub-pixel adjacent thereto through layers included in the light emitting structure EMS can be minimized. Thus, first to third light emitting elements LD1, LD2, and LD3 (e.g., light emitting element) may operate with relatively high reliability.

The cathode electrode CE (or second electrode) may be disposed on the light emitting structure EMS. The cathode electrode CE may be commonly provided in the first to third sub-pixels SP1, SP2, and SP3. The cathode electrode CE may serve as a half mirror which allow light emitted from the light emitting structure EMS to be partially transmitted therethrough and to be partially reflected therefrom.

The first anode electrode AE1, a portion of the light emitting structure EMS, which overlaps the first anode electrode AE1, and a portion of the cathode electrode CE, which overlaps the first anode electrode AE1, may constitute the first light emitting element LD1. The second anode electrode AE2, a portion of the light emitting structure EMS, which overlaps the second anode electrode AE2, and a portion of the cathode electrode CE, which overlaps the second anode electrode AE2, may constitute the second light emitting element LD2. The third anode electrode AE3, a portion of the light emitting structure EMS, which overlaps the third anode electrode AE3, and a portion of the cathode electrode CE, which overlaps the third anode electrode AE3, may constitute the third light emitting element LD3.

An encapsulation layer TFE may be disposed on the cathode electrode CE. The encapsulation layer TFE may prevent oxygen and/or moisture from infiltrating into the light emitting element layer LDL.

An optical functional layer OFL may be disposed on the encapsulation layer TFE. The optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1, CF2, and CF3 respectively corresponding to the first to third sub-pixels SP1, SP2, and SP3. The first to third color filters CF1, CF2, and CF3 may allow lights having different wavelength ranges to pass therethrough. For example, the first to third color filters CF1, CF2, and CF3 may allow light red, green, and blue colors to pass therethrough, respectively.

The first to third color filters CF1, CF2, and CF3 may partially overlap each other in the boundary area BDA. In other embodiments, the first to third color filters CF1, CF2, and CF3 may be spaced apart from each other, and a black matrix may be provided between the first color filter CF1 and the second color filter CF2, between the second color filter CF2 and the third color filter CF3, and between the first color filter CF1 and the third color filter CF3, respectively.

The lens array LA may be disposed on the color filter layer CFL. The lens array LA may include first to third lenses LS1, LS2, and LS3 respectively overlapping the first to third sub-pixels SP1, SP2, and SP3 in the third direction DR3. The first to third lenses LS1, LS2, and LS3 may respectively output lights emitted from the first to third light emitting elements LD1, LD2, and LD3 along intended paths, thereby improving light output efficiency.

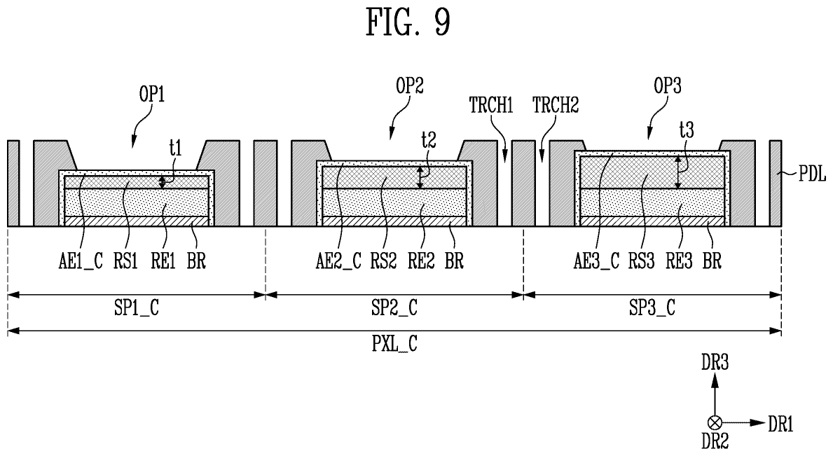

FIG. 9 is a schematic cross-sectional view illustrating a comparative example of the portion of the light emitting element layer shown in FIG. 7.

Referring to FIGS. 8A and 9, a pixel PXL_C shown in FIG. 9 may be substantially identical or similar to the first pixel PXL1 shown in FIG. 8A, except first to third resonant layers RS1, RS2, and RS3 and a first anode electrode AE1_C. Therefore, overlapping descriptions will not be repeated.

The first to third resonant layers RS1, RS2, and RS3 may be disposed on first to third reflective electrodes RE1, RE2, and RE3, respectively. The first to third resonant layers RS1, RS2, and RS3 may be disposed in first to third sub-pixels SP1_C, SP2_C, and SP3_C, respectively.

First to third anode electrodes AE1_C, AE2_C, and AE3_C may be disposed on the first to third resonant layers RS1, RS2, and RS3. The first to third anode electrodes AE1_C, AE2_C, and AE3_C may be disposed in first to third sub-pixels SP1_C, SP2_C, and SP3_C, respectively. The first to third anode electrodes AE1_C, AE2_C, and AE3_C may cover top surfaces and side surfaces of the first to third resonant layers RS1, RS2, and RS3, respectively, and cover side surfaces of the first to third reflective electrodes RE1, RE2, and RE3 disposed under the first to third resonant layers RS1, RS2, and RS3, respectively.

A pixel defining layer PDL may be disposed on the first to third anode electrodes AE1_C, AE2_C, and AE3_C. The pixel defining layer PDL may include first to third openings OP1, OP2, and OP3 respectively exposing portions of the first to third anode electrodes AE1, AE2, and AE3. The first to third openings OP1, OP2, and OP3 of the pixel defining layer PDL may define emission areas of the first to third sub-pixels SP1_C, SP2_C, and SP3_C, respectively.

The first to third resonant layers RS1, RS2, and RS3 may function to adjust a resonance distance such that light can be output in an optimum resonance condition in the first to third sub-pixels SP1_C, SP2_C, and SP3_C. Since it is difficult to adjust resonance distances of the first to third sub-pixels SP1_C, SP2_C, and SP3_C to be equal, e.g., since it is difficult to set a thickness of a light emitting structure EMS, a position of a light emitting layer in the light emitting structure EMS, or the like in a limited range, the resonance distances of the first to third sub-pixels SP1_C, SP2_C, and SP3_C may be individually adjusted using the first to third resonant layers RS1, RS2, and RS3. As described above with reference to FIG. 7, a distance between each of the first to third reflective electrodes RE1, RE2, and RE3 and a cathode electrode CE may be defined as a resonance distance of light emitted from the light emitting layer of the corresponding light emitting structure EMS.

A thickness t1 of the first resonant layer RS1 in the third direction DR3 may be smaller than a thickness t2 of the second resonant layer RS2 in the third direction DR3. Accordingly, the first sub-pixel SP1_C may have a resonance distance shorter than a resonance distance of the second sub-pixel SP2_C. The thickness t2 of the second resonant layer RS2 in the third direction DR3 may be smaller than a thickness t3 of the third resonant layer RS3 in the third direction DR3. Accordingly, the second sub-pixel SP2_C may have a resonance distance shorter than a resonance distance of the third sub-pixel SP3_C. Such an adjusted resonance distance enables light in a specific wavelength range to be effectively and efficiently amplified in each of the first to third sub-pixels SP1_C, SP2_C, and SP3_C.

However, in case that the thicknesses t1, t2, and t3 of the first to third resonant layers RS1, RS2, and RS3 are determined by considering only distances (i.e., resonance distances) between the first to third reflective electrodes RE1, RE2, and RE3 and the cathode electrode CE, light output efficiency (or luminance) may be lowered while the light is absorbed or disappears between the first to third reflective electrodes RE1, RE2, and RE3 and the first to third anode electrodes AE1_C, AE2_C, and AE3_C. A process for forming the first to third resonant layers RS1, RS2, and RS3 having different thicknesses t1, t2, and t3, and therefore, manufacturing processes of the display device may be complicated. Further, the first to third anode electrodes AE1_C, AE2_C, and AE3_C are to be in contact with the first to third reflective electrodes RE1, RE2, and RE3 in a non-emission area such that resonance characteristics of light become uniform in an emission area. Accordingly, there is a limitation in decreasing the non-emission area and increasing the emission area.

Therefore, in the embodiments shown in FIGS. 7 and 8A to 8C, a thickness of the light emitting structure EMS may be set by adjusting a resonance distance of two sub-pixels among three sub-pixels, and only the first sub-pixel SP1 may include a resonant layer by considering the resonance distance of the first sub-pixel SP1. Thus, while the luminance of the display device is improved, manufacturing processes of the display device can be simplified. The pixel defining layer PDL is used as the resonant layer so that the manufacturing processes of the display device may be further simplified. A decrease in size of the emission area of the first sub-pixel SP1 due to the pixel defining layer PDL is excluded, and contact between the second and third anode electrodes AE2 and AE3 and the second and third reflective electrodes RE2 and RE2 at the outside of an emission area is excluded so that the display device having a high opening ratio may be implemented.

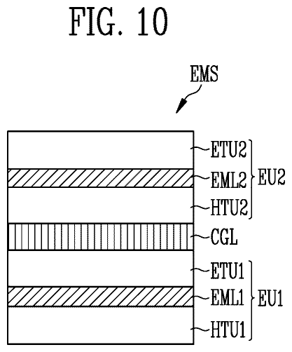

FIG. 10 is a schematic cross-sectional view illustrating an embodiment of a light emitting structure included in any one of the first to third light emitting elements shown in FIG. 7.

Referring to FIG. 10, the light emitting structure EMS may have a tandem structure in which first and second light emitting units EU1 and EU2 are sequentially stacked. The light emitting structure EMS may be substantially identical in each of the first to third light emitting elements LD1, LD2, and LD3 shown in FIG. 7.

Each of the first and second light emitting units EU1 and EU2 may include at least one light emitting layer generating light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, if necessary. The first and second hole transport units HTU1 and HTU2 may have a same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, if necessary. The first and second electron transport units ETU1 and ETU2 may have a same configuration or have different configurations.

A connection layer, which may be provided in the form of a charge generation layer CGL, may be disposed between the first light emitting unit EU1 and the second light emitting unit EU2 to electrically connect the first light emitting unit EU1 and the second light emitting unit EU2 together. The charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments are not limited thereto.

The first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. The second light emitting layer EML2 may include a structure in which a first sub-light emitting layer to generate light of a red color and a second sub-light emitting layer to generate light of a green color are stacked. The light of the red color and the light of the green color may be mixed together to provide the light of the yellow color. An intermediate layer to perform a function of transporting holes and/or a function of blocking transportation of electrodes may be further disposed between the first and second sub-light emitting layers.

The first light emitting layer EML1 and the second light emitting layer EML2 may generate light of a same color.

The light emitting structure EMS may be formed through a process such as vacuum deposition or inkjet printing, but embodiments are not limited thereto.

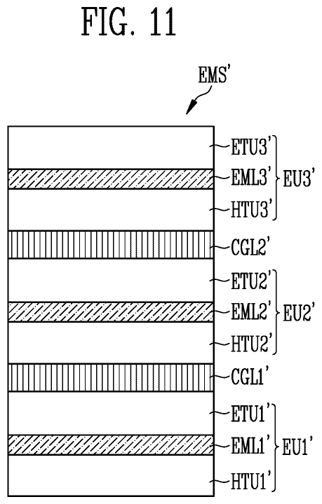

FIG. 11 is a schematic cross-sectional view illustrating another embodiment of the light emitting structure included in the one of the first to third light emitting elements shown in FIG. 7.

Referring to FIG. 11, a light emitting structure EMS' may a tandem structure in which first to third light emitting units EU1′, EU2′, and EU3′ are stacked. The light emitting structure EMS' may be substantially identical in each of the first to third light emitting elements LD1, LD2, and LD3 shown in FIG. 7.

Each of the first to third light emitting units EU1′, EU2′, and EU3′ may include a light emitting layer generating light according to an applied current. The first light emitting unit EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′, HTU2′, and HTU3′ may include at least one of a hole injection layer and a hole transport layer, and further include a hole buffer layer, and an electron blocking layer, and the like, if necessary. The first to third hole transport units HTU1′, HTU2′, and HTU3′ may have a same configuration or have different configurations.

Each of the first to third electron transport units ETU1′, ETU2′, and ETU3′ may include at least one of an electron injection layer and an electron transport layer, and further include an electron buffer layer, a hole blocking layer, and the like, if necessary. The first to third electron transport units ETU1′, ETU2′, and ETU3′ may have a same configuration or have different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

The first to third light emitting layers EML1′, EML2′, and EML3′ may generate lights of different colors. Lights respectively emitted from the first to third light emitting layers EML1′, EML2′, and EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color.

In other embodiments, at least two light emitting layers among the first to third light emitting layers EML1′, EML2′, and EML3′ may generate light of a same color.

Unlike as shown in FIGS. 10 and 11, the light emitting structure EMS shown in FIG. 7 may include one light emitting unit in each of the first to third light emitting elements LD1, LD2, and LD3. The light emitting unit included in each of the first to third light emitting elements LD1, LD2, and LD3 may be to emit lights of different colors. For example, the light emitting unit of the first light emitting element LD1 may emit light of a red color, the light emitting unit of the second light emitting element LD2 may emit light of a green color, and the light emitting unit of the third light emitting element LD3 may emit light of a blue color. Unlike as shown in FIG. 7, light emitting units of the first to third sub-pixels SP1, SP2, and SP3 may be separated from each other, and each of the light emitting units may be disposed in the opening OP of the pixel defining layer PDL. At least some of the first to third color filters CF1, CF2, and CF3 may be omitted.

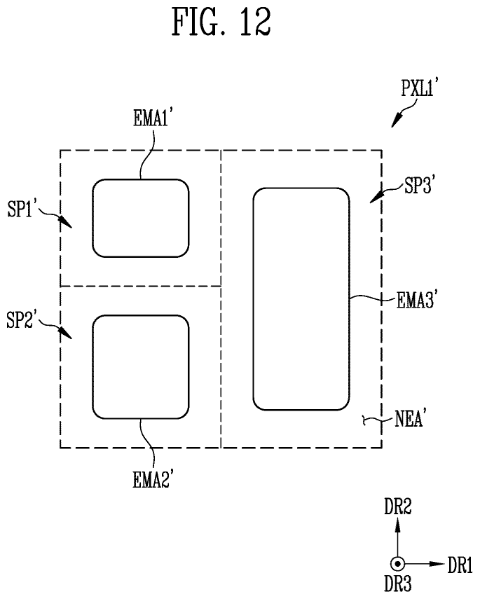

FIG. 12 is a schematic plan view illustrating another embodiment of the one of the pixels shown in FIG. 5.

Referring to FIG. 12, a first pixel PXL1′ may include first to third sub-pixels SP1′, SP2′, and SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than an area of the second sub-pixel SP2′. Accordingly, the second emission area EMA2′ may have an area greater than an area of the first emission area EMA1′, and the third emission area EMA3′ may have an area greater than an area of the second emission area EMA2′. However, embodiments are not limited thereto. For example, the first and second sub-pixels SP1′ and SP2′ may substantially have equal area, and the third sub-pixel SP3′ may have an area greater than an area of each of the first and second sub-pixels SP1′ and SP2′. Areas of the first to third sub-pixels SP1′, SP2′, and SP3′ may be variously modified in other embodiments.

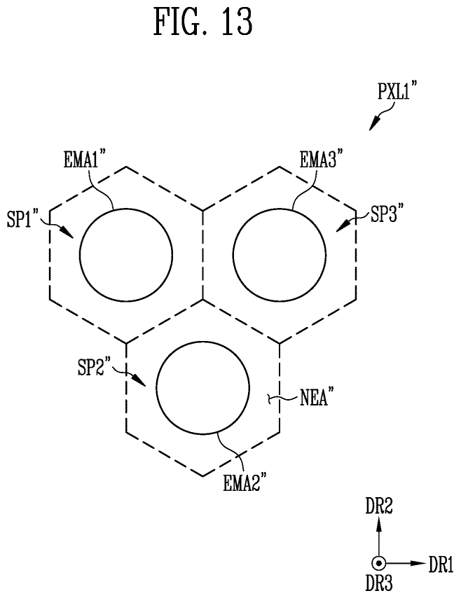

FIG. 13 is a schematic plan view illustrating still another embodiment of the one of the pixels shown in FIG. 5.

Referring to FIG. 13, a first pixel PXL1″ may include first to third sub-pixels SP1″, SP2″, and SP3″. The first sub-pixel SP1″ may include a first emission area EMA1″ and a non-emission area NEA″ at the periphery of the first emission area EMA1″. The second sub-pixel SP2″ may include a second emission area EMA2″ and the non-emission area NEA″ at the periphery of the second emission area EMA2″. The third sub-pixel SP3″ may include a third emission area EMA3″ and the non-emission area NEA″ at the periphery of the third emission area EMA3″.

The first to third sub-pixels SP1″, SP2″, and SP3″ may have polygonal shapes in case that viewed in the third direction DR3. For example, the shapes of the first to third sub-pixels SP1″, SP2″, and SP3″ may be hexagonal shapes as shown in FIG. 13.

The first to third emission areas EMA1″, EMA2″, and EMA3″ may have circular shapes in case that viewed in the third direction DR3. However, embodiments are not limited thereto. For example, each of the first to third emission areas EMA1″, EMA2″, and EMA3″ may have a polygonal shape.

The first and third sub-pixels SP1″ and SP3″ may be arranged in the first direction DR1. The second sub-pixel SP2″ may be disposed in a direction (or diagonal direction) inclined by an acute angle, based on the second direction DR2, with respect to the first sub-pixel SP1″.

The arrangements of the sub-pixels, which are shown in FIGS. 6, 12, and 13, are merely illustrative, and embodiments are not limited thereto. Each pixel may include two or more sub-pixels, and the sub-pixels may be arranged in various manners. Each of the sub-pixels may have various shapes, and an emission area EMA of the sub-pixel may have various shapes.

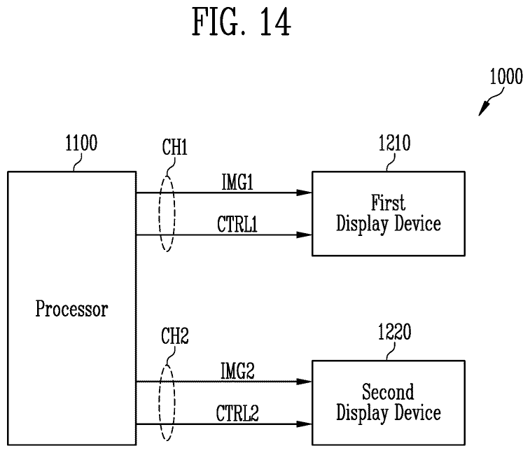

FIG. 14 is a schematic block diagram illustrating an embodiment of a display system.

Referring to FIG. 14, a display system 1000 may include a processor 1100 and one or more display devices 1210 and 1220.

The processor 1100 may perform various tasks and various calculations. The processor 1100 may include an Application Processor (AP), a Graphics Processing Unit (GPU), a microprocessor, a Central Processing Unit (CPU), and the like. The processor 1100 may be electrically connected to other components of the display system 1000 through a bus system to control the components of the display system 1000.

In FIG. 14, the display system 1000 may include first and second display devices 1210 and 1220. The processor 1100 may be electrically connected to the first display device 1210 through a first channel CH1, and be electrically connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be identical to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1. The second image data IMG2 and the second control signal CTRL2 may be respectively provided as the image data IMG and the control signal CTRL, which are shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

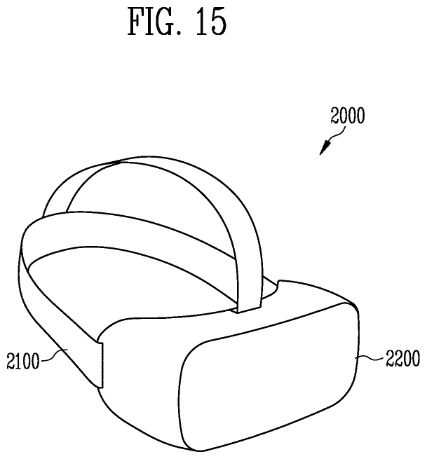

FIG. 15 is a schematic perspective view illustrating an application example of the display system shown in FIG. 14.

Referring to FIG. 15, the display system 1000 shown in FIG. 14 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be electrically connected to the display device accommodating case 2200. The head mounting band 2100 may include a horizontal band and/or a vertical band, used to fix the head mounted display device 2000 to the head of the user. The horizontal band may be to surround a side portion of the head of the user, and the vertical band may be to surround an upper portion of the head of the user. However, embodiments are not limited thereto. For example, the head mounting band 2100 may be implemented in the form of a glasses frame, a helmet or the like.

The display device accommodating case 2200 may accommodate the first and second display devices 1210 and 1220 shown in FIG. 14. The display device accommodating case 2200 may further accommodate the processor 1100 shown in FIG. 14.

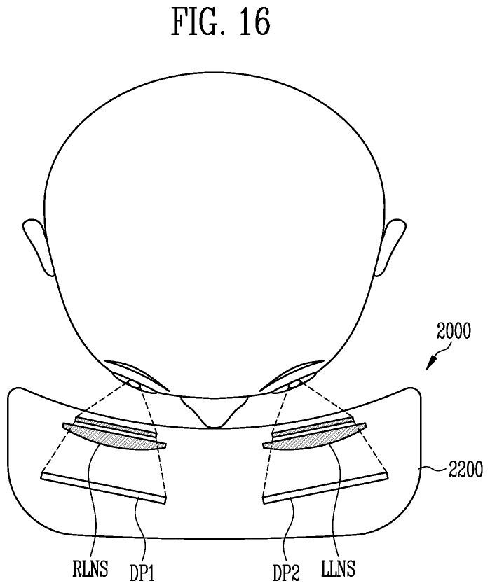

FIG. 16 is a schematic view illustrating a head-mounted display device shown in FIG. 14, which is worn by a user.

Referring to FIG. 16, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

Each of the right-eye lens RLNS and the left-eye lens LLNS may include an optical lens having a pancake-shaped section. In embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

A method of manufacturing the display device in accordance with the above-described embodiment will be described.

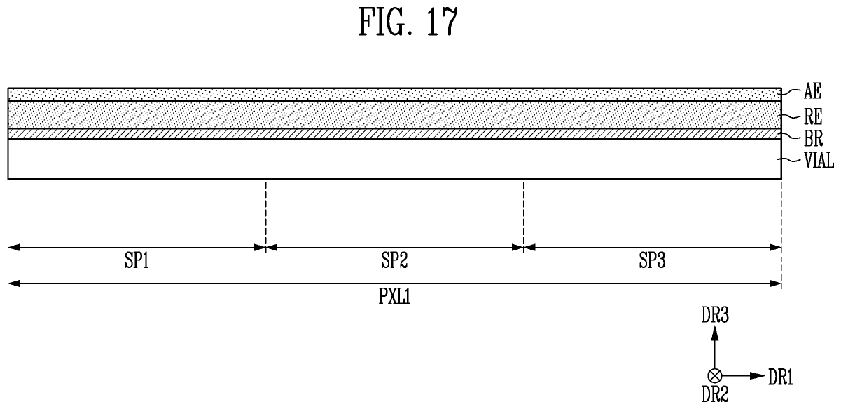

FIGS. 17 to 23 are schematic cross-sectional views illustrating process steps of a method of manufacturing a display device in accordance with an embodiment of the disclosure. FIGS. 17 to 23 are schematic cross-sectional views illustrating a method of manufacturing the display device shown in FIGS. 1 to 8A. For convenience of description, configurations shown in FIGS. 17 to 23 are briefly illustrated, and detailed reference numerals are omitted.

Referring to FIGS. 17 to 19, first to third reflective electrodes RE1, RE2, and RE3 of first to third sub-pixels SP1, SP2, and SP3 are formed on a via layer VIAL, and second and third anode electrodes AE2 and AE3 of the second and third sub-pixels SP2 and SP3 are formed.

As shown in FIG. 17, first, a barrier layer BR, a reflective electrode RE, and an anode electrode AE (or electrode layer) are disposed on the via layer VIAL. The barrier layer BR may be disposed on the via layer VIAL. The reflective electrode RE may be disposed on the barrier layer BR. A thickness of each of the first to third reflective electrodes RE1, RE2, and RE3 may be in a range of about 700 Å to about 1000 Å. For example, the thickness of each of the first to third reflective electrodes RE1, RE2, and RE3 may be about 850 Å, but the disclosure is not limited thereto. The anode electrode AE (or electrode layer) may be formed on the reflective electrode RE. A thickness of the anode electrode AE (or electrode layer) may be in a range of about 50 Å to about 100 Å. The thickness of the anode electrode AE (or electrode layer) may be about 60 Å, but the disclosure is not limited thereto.

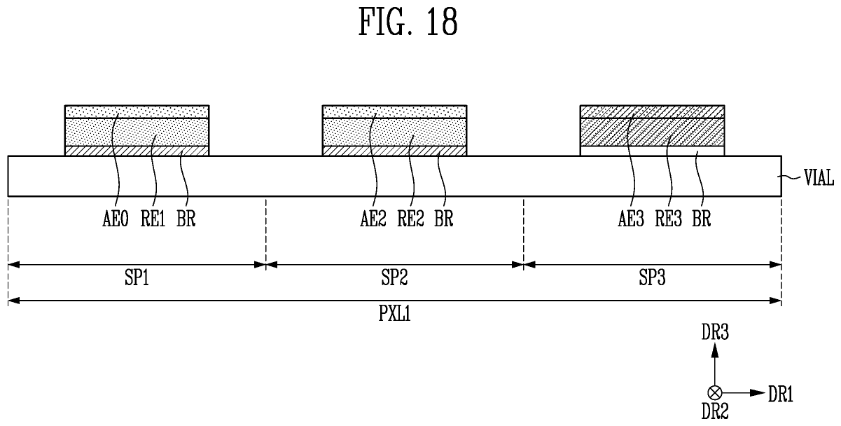

As shown in FIG. 18, the barrier layer BR, the reflective electrode RE, and the anode electrode AE (or electrode layer) are patterned. The barrier layer BR, the reflective electrode RE, and the anode electrode AE (or electrode layer) are etched between the first to third sub-pixels SP1, SP2, and SP3. Accordingly, the first to third reflective electrodes RE1, RE2, and RE3 and zeroth, second, and third anode electrodes AE0, AE2, and AE3 may be formed in the first to third sub-pixels SP1, SP2, and SP3, respectively.

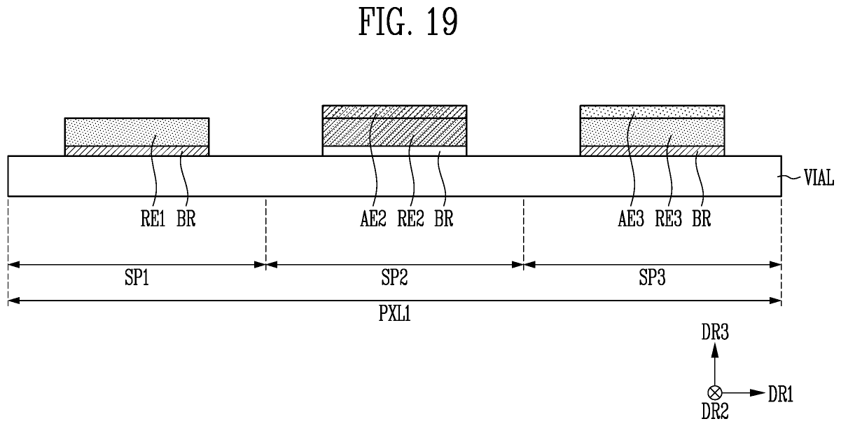

As shown in FIG. 19, only the zeroth anode electrode AE0 of the first sub-pixel SP1 is etched.

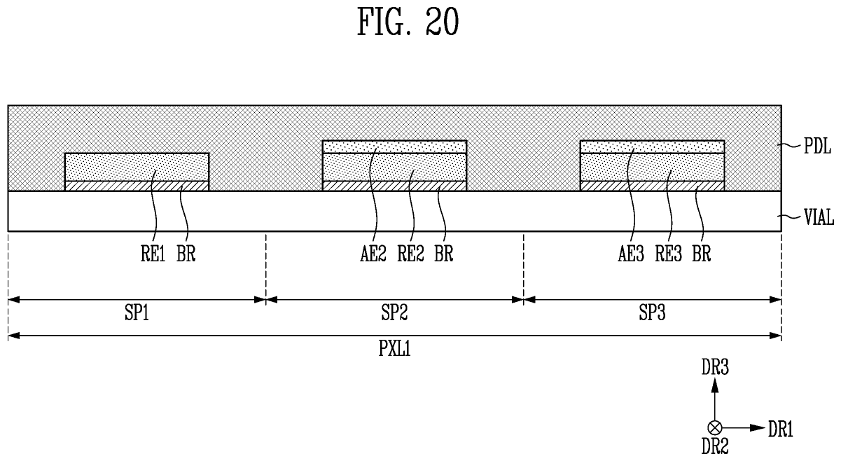

Referring to FIG. 20, a pixel defining layer PDL is disposed on the first reflective electrode RE1 for the first sub-pixel SP1 and the second and third anode electrodes AE2 and AE3 for the second and third sub-pixels SP2 and SP3. The pixel defining layer PDL may have a single layer or a multi-layer structure. As described with reference to FIG. 8B, in case that the pixel defining layer PDL includes first to third layers L1, L2, and L3, the first to third layers L1, L2, and L3 may be sequentially disposed. A top surface of the pixel defining layer PDL may be formed flat through Chemical Mechanical Polishing (CMP).

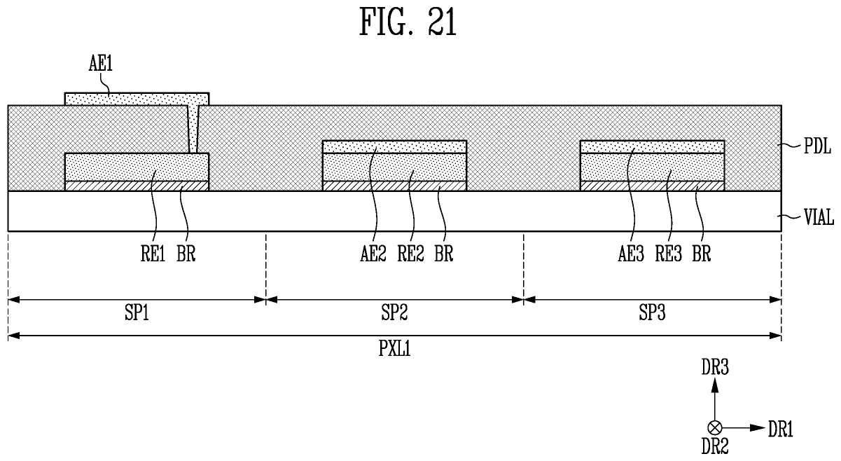

Referring to FIG. 21, a first anode electrode AE1 of the first sub-pixel SP1 is disposed on the pixel defining layer PDL. The first anode electrode AE1 may be electrically connected to the first reflective electrode RE1 through a contact hole partially penetrating the pixel defining layer PDL.

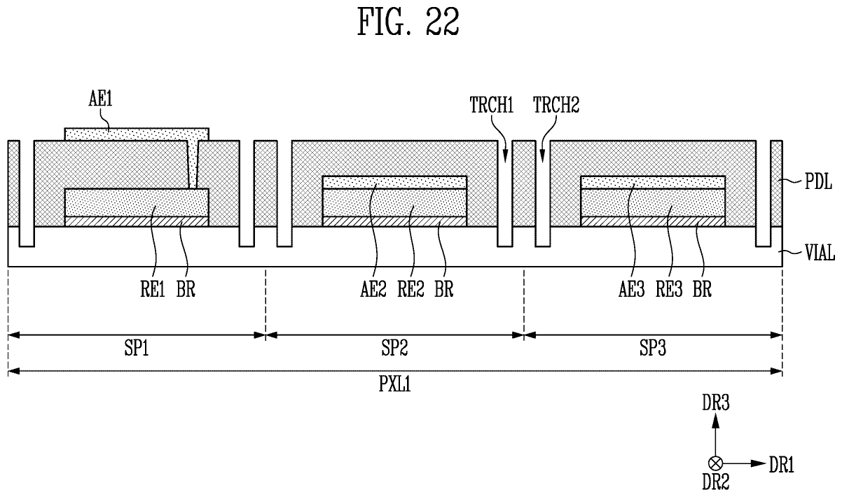

Referring to FIG. 22, trenches TRCH1 and TRCH2 are formed in the pixel defining layer PDL. The trenches TRCH1 and TRCH2 may be disposed between the first to third sub-pixels SP1, SP2, and SP3. Due to the trenches TRCH1 and TRCH2, portions of a light emitting structure EMS, which are included in the first to third sub-pixels SP1, SP2, and SP3, may be at least partially separated from each other. Accordingly, a current leaked from each of the first to third sub-pixels SP1, SP2, and SP3 to a sub-pixel adjacent thereto through layers included in the light emitting structure EMS may be minimized, which has been described above.

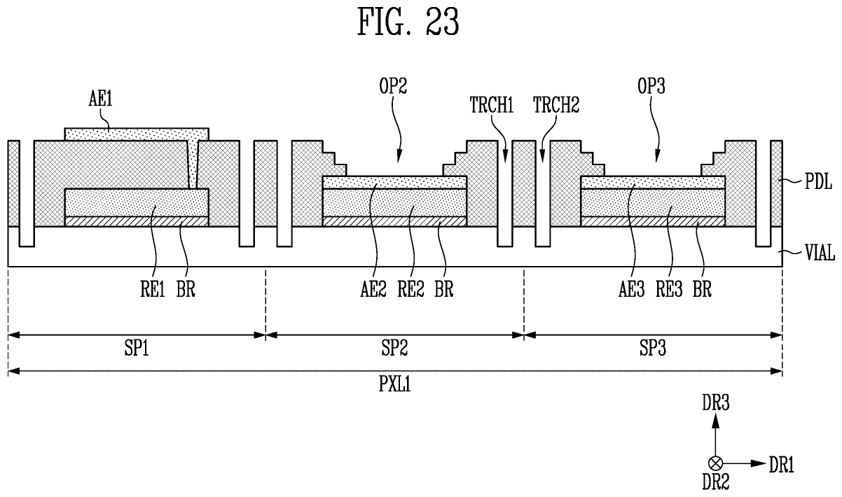

Referring to FIG. 23, subsequently, second and third openings OP2 and OP3 are formed in the pixel defining layer PDL of the second and third sub-pixels SP2 and SP3. The second and third openings OP2 and OP3 may expose the second and third anode electrodes AE2 and AE3, respectively.

Subsequently, as described with reference to FIG. 7, the light emitting structure EMS and the like are formed on the first to third anode electrodes AE1, AE2, and AE3 and the pixel defining layer PDL, thereby completing the display device.

As depicted in FIGS. 21 to 23, a step of forming the first anode electrode AE1, a step of forming the trenches TRCH1 and TRCH2, and a step of forming the second and third openings OP2 and OP3 may be sequentially performed. However, the disclosure is not limited thereto. For example, some of the steps may be simultaneously performed, or the order of at least some of the steps may vary.

Meanwhile, a step of forming a protrusion pattern PRT (see FIG. 8C) may be performed instead of the step of forming the trenches TRCH1 and TRCH2 shown in FIG. 22.

In the display device in accordance with the disclosure, a resonance distance of a sub-pixel can be adjusted using a pixel defining layer disposed between a reflective electrode and an anode electrode. Accordingly, light in a corresponding wavelength range can be efficiently output in the sub-pixel, and the luminance of the display device can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a first sub-pixel, a second sub-pixel, and a third sub-pixel,
wherein each of the first sub-pixel, the second sub-pixel, and the third sub-pixel includes:
a reflective electrode disposed on a base layer;
a first electrode disposed on the reflective electrode;
a pixel defining layer disposed on the reflective electrode;
a light emitting member disposed on the first electrode and the pixel defining layer; and
a second electrode disposed on the light emitting member,
the first electrode of the first sub-pixel is disposed on the pixel defining layer, and
the first electrode of the second sub-pixel is disposed between the reflective electrode and the pixel defining layer.

2. The display device of claim 1, wherein the first electrode of the third sub-pixel is disposed between the reflective electrode and the pixel defining layer.

3. The display device of claim 1, wherein the first electrode of the first sub-pixel is electrically connected to the reflective electrode of the first sub-pixel through a contact hole at least partially penetrating the pixel defining layer, and
the first electrode of the second sub-pixel is disposed on the reflective electrode of the second sub-pixel and is in direct contact with the reflective electrode of the second sub-pixel.

4. The display device of claim 1, wherein the pixel defining layer includes at least one of silicon oxide and silicon nitride.

5. The display device of claim 1, wherein a distance between the reflective electrode and the first electrode in the first sub-pixel is about ¼ of a wavelength band of light which the first sub-pixel emits to an outside.

6. The display device of claim 1, wherein the first sub-pixel emits light in a red wavelength band, and a thickness of the pixel defining layer on the reflective electrode is in a range of about 1500 Å to about 1900 Å.

7. The display device of claim 6, wherein a distance between the reflective electrode and the first electrode in the first sub-pixel is about 1700 Å.

8. The display device of claim 1, wherein the pixel defining layer includes an opening exposing the first electrode of the second sub-pixel, and includes no opening overlapping the first sub-pixel.

9. The display device of claim 8, wherein, in a plan view, an emission area of the first sub-pixel overlaps the first electrode of the first sub-pixel, and an emission area of the second sub-pixel overlaps the opening smaller than the first electrode of the second sub-pixel.

10. The display device of claim 1, wherein the pixel defining layer includes a first layer, a second layer disposed on the first layer, and a third layer disposed on the second layer.

11. The display device of claim 1, wherein the first electrode includes a titanium, titanium nitride, or tantalum nitride.

12. The display device of claim 1, wherein the first electrode includes indium tin oxide, indium zinc oxide, zinc oxide, indium gallium zinc oxide, or indium tin zinc oxide.

13. The display device of claim 1, wherein the light emitting member includes a first light emitting layer emitting light of a first color and a second light emitting layer which is disposed on the first light emitting layer and emits light of a second color different from the first color.

14. A wearable electronic device comprising:
a display panel outputting light; and
at least one lens disposed on the display panel,
wherein the display panel includes a first sub-pixel, a second sub-pixel, and a third sub-pixel,
each of the first sub-pixel, the second sub-pixel, and the third sub-pixel includes:
a reflective electrode disposed on a base layer;
a first electrode disposed on the reflective electrode;
a pixel defining layer disposed on the reflective electrode;
a light emitting member disposed on the first electrode and the pixel defining layer; and
a second electrode disposed on the light emitting member,
the first electrode of the first sub-pixel is disposed on the pixel defining layer, and
the first electrode of the second sub-pixel is disposed between the reflective electrode and the pixel defining layer.

15. A method of manufacturing a display device, the method comprising:
forming, on a base layer, a reflective electrode of each of a first sub-pixel, a second sub-pixel, and a third sub-pixel;
forming a first electrode of the second sub-pixel on the reflective electrode;
forming a pixel defining layer covering the first electrode of the second sub-pixel;
forming a first electrode of the first sub-pixel on the pixel defining layer;
forming, in the pixel defining layer, an opening exposing the first electrode of the second sub-pixel; and
forming a light emitting member on the first electrode of the first sub-pixel and the first electrode of the second sub-pixel, which is exposed by the opening.

16. The method of claim 15, wherein, between the base layer and the light emitting member, the third sub-pixel and the second sub-pixel include a same stacked structure.

17. The method of claim 15, wherein the first electrode of the first sub-pixel is electrically connected to the reflective electrode of the first sub-pixel through a contact hole penetrating the pixel defining layer, and
the first electrode of the second sub-pixel is disposed on the reflective electrode of the second sub-pixel and is in direct contact with the reflective electrode of the second sub-pixel.

18. The method of claim 15, wherein the forming of the first electrode of the second sub-pixel includes:
forming an electrode layer for the first electrode on the reflective electrode;
etching the reflective electrode and the electrode layer between the first to third sub-pixels; and
etching the electrode layer on the first sub-pixel.

19. The method of claim 15, wherein the pixel defining layer includes at least one of silicon oxide and silicon nitride.

20. The method of claim 15, wherein the first electrode of each of the first to third sub-pixels includes a titanium, titanium nitride, or tantalum nitride.
